(19) United States
(12) Patent Application Publication
(10) Pub. No.: US 2024/0332016 A1
(43) Pub. Date: Oct. 3, 2024

(54) METHODS FOR SILICON GERMANIUM UNIFORMITY CONTROL USING MULTIPLE PRECURSORS

(71) Applicant: ASM IP Holding B.V., Almere (NL)

(72) Inventors: Amir Kajbafvala, Chandler, AZ (US); Peter Westrom, Payson, AZ (US); Joe Margetis, Gilbert, AZ (US); Xin Sun, Tempe, AZ (US); Caleb Miskin, Mesa, AZ (US); Yen Lin Leow, Grenoble (FR); Yanfu Lu, Phoenix, AZ (US)

(21) Appl. No.: 18/742,250

(22) Filed: Jun. 13, 2024

Related U.S. Application Data
(62) Division of application No. 17/317,965, filed on May 12, 2021, now Pat. No. 12,057,314.
(60) Provisional application No. 63/025,499, filed on May 15, 2020.

(51) Int. Cl. H01L 21/02; C23C 16/08; C23C 16/455; C23C 16/52; C30B 25/16; C30B 25/18; C30B 29/52

(52) U.S. Cl. CPC H01L 21/0262; C23C 16/08; C23C 16/45512; C23C 16/52; C30B 25/165; C30B 25/186; C30B 29/52; H01L 21/02532

(57) ABSTRACT

A method of forming a silicon germanium layer on a surface of a substrate and a system for forming a silicon germanium layer are disclosed. Examples of the disclosure provide a method that includes providing a plurality of growth precursors to control and/or promote parasitic gas-phase and surface reactions, such that greater control of the film (e.g., thickness and/or composition) uniformity can be realized.

### CROSS-REFERENCE TO RELATED APPLICATIONS

This application is a divisional of, and claims priority to and the benefit of, U.S. patent application Ser. No. 17/317,965, filed May 12, 2021 and entitled “METHODS FOR SILICON GERMANIUM UNIFORMITY CONTROL USING MULTIPLE PRECURSORS,” which is a nonprovisional of, and claims priority to and the benefit of, U.S. Provisional Patent Application No. 63/025,499, filed May 15, 2020 and entitled “METHODS FOR SILICON GERMANIUM UNIFORMITY CONTROL USING MULTIPLE PRECURSORS,” which are hereby incorporated by reference herein.

### FIELD OF THE DISCLOSURE

The present disclosure generally relates to gas-phase reactor systems and methods. More particularly, the disclosure relates to methods and systems for forming silicon germanium layers.

### BACKGROUND OF THE DISCLOSURE

Gas-phase reactors, such as chemical vapor deposition (CVD) reactors, can be used for a variety of applications, including depositing materials on a substrate surface. For example, gas-phase reactors can be used to deposit layers on a substrate to form semiconductor devices, flat panel display devices, photovoltaic devices, microelectromechanical systems (MEMS), and the like.

By way of examples, such reactors can be used to form silicon germanium layers on a surface of a substrate. The silicon germanium layers can be used for a variety of applications, including the formation of three-dimensional devices, such as gate-all-around devices and/or as channel, source, and/or drain regions in metal oxide semiconductor (MOS) devices, and particularly complimentary MOS (CMOS) devices.

A typical gas-phase reactor system includes a reactor including a reaction chamber, a precursor gas source fluidly coupled to the reaction chamber, a carrier and/or purge gas source fluidly coupled to the reaction chamber, a gas delivery system to deliver gases (e.g., precursors and/or carrier/purge gas(es)) to the reaction chamber, and an exhaust source fluidly coupled to the reaction chamber.

Generally, it is desirable to have uniform film properties (e.g., film thickness and film composition) across a surface of a substrate and/or to have control over any desired variation of the film properties. As sizes of features formed on a substrate surface decrease, it becomes increasingly important to control film properties, such as film thickness, composition, and resistivity. For example, in the case of silicon germanium layers, it is often desirable to control the silicon and germanium concentration in the layer, as well as the layer thickness across a surface of a substrate. However, with many processes, a thickness and/or composition of a film can undesirably vary across a surface of a substrate, particularly at an edge of a substrate. Accordingly, improved methods and systems for forming silicon germanium layers on a surface of a substrate are desired.

Any discussion, including discussion of problems and solutions, set forth in this section has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various embodiments of the present disclosure relate to methods of forming a silicon germanium layer on a surface of a substrate. While the ways in which various embodiments of the present disclosure address drawbacks of prior methods of forming silicon germanium layers are discussed in more detail below, in general, various embodiments of the disclosure provide multiple silicon precursors to the reaction chamber to provide improved silicon germanium layer composition and/or thickness uniformity in silicon germanium films formed using the methods.

In accordance with exemplary embodiments of the disclosure, a method of forming a silicon germanium layer on a surface of a substrate is provided. The method can include providing a substrate within a reaction chamber, providing a first silicon precursor to the reaction chamber, providing a second silicon precursor to the reaction chamber, and providing a germanium precursor to the reaction chamber. Before any of the foregoing method steps, a precoating layer may be disposed on a surface(s) within the reaction chamber (e.g., the reaction chamber inner walls, the susceptor, thermocouple ring, getter plate, or any other surfaces within the reaction chamber). The precoating layer may comprise a substance or compound comprised in one or more of the precursors for the main deposition process, or in the resulting silicon germanium layer. Accordingly, the precoating layer may comprise silicon and/or germanium. The steps of providing the first silicon precursor to the reaction chamber, providing the second silicon precursor to the reaction chamber, and providing the germanium precursor to the reaction chamber can overlap, such that all three steps of providing the first silicon precursor to the reaction chamber, providing the second silicon precursor to the reaction chamber, and providing the germanium precursor to the reaction chamber occur for a time period. In accordance with examples of these embodiments, the first silicon precursor comprises a halogenated silicon precursor. In accordance with further examples, the second silicon precursor comprises a nonhalogenated silicon precursor.

In accordance with further examples of the disclosure, a structure comprising the silicon germanium layer is provided. The silicon germanium layer can be formed according to a method disclosed herein.

In accordance with further examples of the disclosure, a device comprising the silicon germanium layer is provided. The device can be formed using a structure as described herein. The silicon germanium layer can be formed according to a method disclosed herein.

In accordance with yet further embodiments of the disclosure, a system is provided. The system can include one or more reaction chambers, a first silicon precursor source, a second silicon precursor source, a germanium precursor source, an exhaust source, and a controller. In accordance with examples of these embodiments, the controller is configured to control gas flow of a first silicon precursor, a second silicon precursor, and a germanium precursor into at least one of the one or more reaction chambers to form a layer comprising silicon germanium overlying a surface of a substrate using a deposition process. Exemplary systems can be used to perform methods as disclosed herein and/or to form structures as disclosed herein.

These and other embodiments will become readily apparent to those skilled in the art from the following detailed description of certain embodiments having reference to the attached figures; the disclosure not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one exemplary embodiment of the present disclosure.

FIG. 2 illustrates a system in accordance with at least one exemplary embodiment of the present disclosure.

FIG. 3 schematically illustrates a gas injection system for use in accordance with at least one exemplary embodiment of the disclosure.

FIG. 4 illustrates a cross-sectional view of a flange for use in accordance with at least one exemplary embodiment of the disclosure.

FIG. 5 illustrates a structure in accordance with at least one exemplary embodiment of the disclosure.

FIG. 6 illustrates a composition profile of a silicon germanium layer formed using a method in accordance with at least one embodiment of the disclosure.

FIG. 7A illustrates a thickness profile of silicon germanium layers formed using methods in accordance with at least one embodiment of the disclosure.

FIG. 7B illustrates a composition profile of silicon germanium layers formed using methods in accordance with at least one embodiment of the disclosure.

FIG. 8A illustrates a thickness profile of silicon germanium layers formed using methods in accordance with at least one embodiment of the disclosure.

FIG. 8B illustrates a composition profile of silicon germanium layers formed using methods in accordance with at least one embodiment of the disclosure.

FIG. 9A illustrates a thickness profile of silicon germanium layers formed using methods in accordance with at least one embodiment of the disclosure.

FIG. 9B illustrates a composition profile of silicon germanium layers formed using methods in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to methods and systems of forming a silicon germanium layer (i.e., a film) on a surface of a substrate and to structures and devices including such layers. Exemplary methods and systems can be used to form the silicon germanium layer with relatively low variation of film thickness and/or composition across the layer, even near the edge (e.g., within 1 mm of the edge) of a substrate, such as a wafer, compared to traditional techniques for forming such layers.

Examples described herein can be used to form or grow epitaxial (e.g., two-component and/or additionally doped) silicon germanium layers on a surface of a substrate. Exemplary methods described herein may be particularly useful in forming films having relatively high germanium concentrations (e.g., greater than about 30 percent, about 20 percent or about 10 percent) and/or in applications in which variation of germanium concentration of the silicon germanium layer is desirably low.

As used herein, the terms precursor and/or reactant can refer to one or more gases/vapors that take part in a chemical reaction or from which a gas-phase substance that takes part in a reaction is derived. The chemical reaction can take place in the gas phase and/or between a gas phase and a surface of a substrate and/or a species on a surface of a substrate.

In this disclosure, the term gas can refer to material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, such as a multi-port injection system, or the like, can be used for, e.g., sealing the reaction space, and can include a seal gas, such as a rare gas. In some cases, the term precursor can refer to a compound that participates in the chemical reaction that produces another compound. The term inert gas can refer to a gas that does not take part in a chemical reaction and/or does not become a part of a film to an appreciable extent. Exemplary inert (e.g., carrier or purge) gases include He, Ar, H₂, N₂, and any combination thereof.

As used herein, the term substrate can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor, and can include one or more layers overlying or underlying the bulk material. Further, the substrate can include various features, such as recesses, protrusions, and the like formed within or on at least a portion of a layer or surface of the substrate.

As used herein, the term epitaxial layer can refer to a substantially single crystalline layer upon an underlying substantially single crystalline substrate or layer.

As used herein, the term chemical vapor deposition can refer to any process wherein a substrate is exposed to one or more gas-phase precursors, which react and/or decompose on a substrate surface to produce a desired deposition.

As used herein, the terms film and/or layer can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term structure can refer to a substrate as described herein, and/or a substrate including one or more layers overlying the substrate, such as one or more layers formed according to a method as described herein.

As used herein, the term silicon germanium layer can refer to a layer that includes silicon and germanium. In some cases, the layer can consist essentially of silicon and germanium. In some cases, the silicon germanium layer can include additional dopants, such as p-type dopants and/or n-type dopants. In accordance with various examples of the disclosure, a composition of a silicon germanium layer can be represented as Si₁₋ₓGeₓ wherein 1≥x≥0, or 0.8≥x≥0.1, or 0.6≥x≥0.2, or materials comprising silicon and germanium having compositions as set forth herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

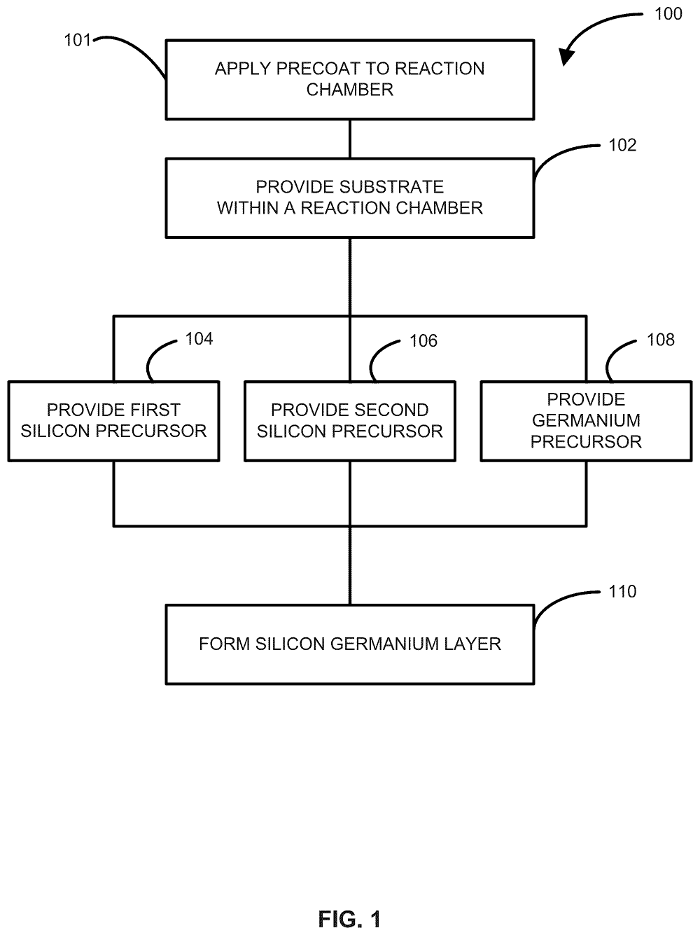

Turning now to the figures, FIG. 1 illustrates a method 100 in accordance with examples of the disclosure. Method 100 includes the steps of providing a substrate within a reaction chamber (step 102), providing a first silicon precursor to the reaction chamber (step 104), providing a second silicon precursor to the reaction chamber (step 106), providing a germanium precursor to the reaction chamber (step 108), and forming the silicon germanium layer (step 110). In various embodiments, method 100 may further comprising precoating the reaction chamber (step 101). The precoat, as discussed in further detail herein, may be applied to the reaction chamber such that any or all surfaces within the reaction chamber (and surfaces of any components within the reaction chamber, such as susceptor 216, thermocouple ring 217, and/or getter plate 219) receives a precoat disposed thereon. The precoat may be applied before or after a substrate is disposed or provided in the reaction chamber.

During step 102, a substrate is provided within a reaction chamber. As a non-limiting example, the reaction chamber used during step 102 may comprise a reaction chamber of a chemical vapor deposition (e.g., epitaxial) system. However, it is also contemplated that other reaction chambers and alternative chemical vapor deposition systems may also be utilized to perform the embodiments of the present disclosure. The reaction chamber can be a stand-alone reaction chamber or part of a cluster tool.

Step 102 can include heating the substrate to a desired deposition temperature within the reaction chamber. In some embodiments of the disclosure, step 102 includes heating the substrate to a temperature of less than approximately 1100° C., or to a temperature of less than approximately 850° C., or to a temperature of less than approximately 700° C., or to a temperature of less than approximately 650° C., or to a temperature of less than approximately 600° C., or to a temperature of less than approximately 550° C., or to a temperature of less than approximately 500° C., or to a temperature of less than approximately 450° C., or to a temperature of less than approximately 400° C., or even to a temperature of less than approximately 300° C. For example, in some embodiments of the disclosure, heating the substrate to a deposition temperature may comprise heating the substrate to a temperature between approximately 400° C. and approximately 1100° C. or approximately 400° C. and approximately 700° C.

In addition to controlling the temperature of the substrate, a pressure within the reaction chamber may also be regulated. For example, in some embodiments of the disclosure, the pressure within the reaction chamber during step 102 may be less than 760 Torr, or less than 350 Torr, or less than 100 Torr, or less than 50 Torr, or less than 25 Torr, or less than 10 Torr, or even less than 5 Torr. In some embodiments, the pressure in the reaction chamber may be between 5 Torr and 760 Torr, between 10 Torr and 200 Torr, or between 10 Torr and 100 Torr. A temperature and/or pressure for steps 104-110 can be the same or similar to the temperature and/or pressure of step 102.

During steps 104-108, precursors are flowed to the reaction chamber. In accordance with examples of the disclosure, steps 104-108 overlap in time, and can substantially overlap, such that steps 104, 106, and 108 each start at about the same time and each end at about the same time. In various embodiments, steps 104-108 may occur at different times (e.g., sequentially).

During step 104, the first silicon precursor is provided to the reaction chamber. Exemplary silicon precursors suitable for use as the first silicon precursor include a halogenated silicon precursor. In this context, a halogenated silicon precursor includes a silicon precursor that includes a halogen, such as one or more of fluorine, chlorine, bromine, and iodine. Exemplary halogenated silicon precursors can be represented by a formula SiₓW_{y}H_{z}, wherein W is a halide selected from the group consisting of fluorine, chlorine, bromine, and iodine, x and y are integers greater than zero, and z is an integer greater than or equal to zero. Halogenated silicon precursors can include a single species of halogens, such as of fluorine, chlorine, bromine, or iodine (e.g., chlorine), or can include two or more different species of halogens, such as chlorine and bromine, or the like. By way of particular examples, the halogenated silicon precursor can include the halogenated silicon precursor comprising a compound selected from the group consisting of trichlorosilane, dichlorosilane, silicon tetrachloride, a silicon bromide, a silicon iodide, or the like. In accordance with examples of the disclosure, the halogenated silicon precursor does not contain fluorine.

A flowrate of the first silicon precursor to the reaction chamber during step 104 can range from about 100 to about 1500 sccm, about 100 to about 1000, about 100 to about 300, about 10 to about 100 sccm, or 1 to about 10 sccm, alone or with a carrier gas, such as hydrogen or helium.

During step 106, the second silicon precursor is provided to the reaction chamber. The second silicon precursor can include a nonhalogenated silicon precursor. In this context, a nonhalogenated silicon precursor is a silicon precursor that does not include a halogen. Exemplary nonhalogenated silicon precursors can include, for example, a compound that includes, or in some cases consists essentially of, silicon and hydrogen. In some cases, the second silicon precursor comprises a silane, such as silane, disilane, trisilane, or the like. Silanes can be represented by the general formula SiₙH₂ₙ₊₂, wherein n is an integer.

A flowrate of the second silicon precursor to the reaction chamber during step 106 can range from about 100 to about 1500 sccm, about 100 to about 1000, about 100 to about 300, about 10 to about 100 sccm, or 1 to about 10 sccm, alone or with a carrier gas, such as hydrogen or helium.

During step 108, the germanium precursor is provided to the reaction chamber. The germanium precursor can include a nonhalogenated, or in some cases can include a halogenated germanium precursor. In this context, halogenated germanium precursors include one or more halogens (of like or different species) and nonhalogenated germanium precursors do not include a halogen. Exemplary nonhalogenated germanium precursors can include, for example, a compound that includes, or in some cases consists essentially of, germanium and hydrogen. In some cases, the germanium precursor can be or include a germane, such as germane, digermane, trigermane or the like. Germanes can be represented by the general formula GeₙH₂ₙ₊₂, wherein n is an integer. Exemplary halogenated germanium precursors include one or more of germanium tetrachloride, germanium chlorohydride, germanium chlorobromide, or the like.

A flowrate of the germanium precursor to the reaction chamber during step 108 can range from about 100 to about 1000 sccm, about 10 to about 100 sccm, or 1 to about 10 sccm, alone or with a carrier gas, such as hydrogen or helium.

A volumetric amount of the first silicon precursor, the second silicon precursor, and/or the germanium precursor can be manipulated to obtain desired layer properties (e.g., composition and/or thickness uniformity). By way of examples, a volumetric flow can include about 10 to about 90, about 1 to about 10, or about 0.1 to about 1 volumetric percent first silicon precursor, about 10 to about 90, about 1 to about 10, or about 0.1 to about 1 volumetric percent second silicon precursor, and/or about 10 to about 90, about 1 to about 10, or about 0.1 to about 1 volumetric percent germanium precursor.

In accordance with further examples of the disclosure, method 100 can include a step of mixing two or more of the first silicon precursor, the second silicon precursor, and the germanium precursor prior to the precursors entering the reaction chamber. For example, the first silicon precursor and the germanium precursor can be mixed to form a mixture prior to flowing the mixture into the reaction chamber. Further, as set forth in more detail below, flowrates of the mixture and/or individual precursors can be controlled into various channels of a gas injection system. This allows further tuning of desired precursor flowrates to particular areas within the reaction chamber, which in turn, allows for additional control of silicon germanium layer properties, such as thickness and/or composition.

During step 110, silicon germanium layer is formed on a surface of the substrate. Although illustrated as a separate step, step 110 can occur as steps 104-108 begin. During step 110, the silicon germanium layer can be epitaxially formed—e.g., overlying a silicon or another silicon germanium or other layer.

In various embodiments, a precoating may be applied to the reaction chamber (step 101) to form a precoat layer (i.e., a seasoning layer) prior to the substrate being processed with the precursors discussed in steps 104-108. The precoat may be applied to the reaction chamber before the substrate is provided therein. The precoat may be applied to any or all surfaces within the reaction chamber. For example, the substrate support surface of a susceptor may receive a precoat layer, as well as the thermocouple ring surrounding the susceptor, the reaction chamber inner walls, and/or a getter plate. In various embodiments, a sacrificial substrate may be disposed on the susceptor before the precoat is applied, and removed after precoating (to be replaced by a substrate for deposition processing). Therefore, in various embodiments, a precoating may be applied to only the portion of the substrate support surface that extends beyond the surface occupied by the substrate (i.e., a rim of the susceptor).

In various embodiments, a precoat layer (or reactants to form a precoat layer) may comprise any suitable composition. For example, in preparation for processing involving silicon germanium deposition on a substrate, the precoat layer (or the reactants therefor) may comprise silicon germanium and/or polycrystalline silicon. In various embodiments, the precoat layer may comprise a compound or substance comprised in at least one of the reactants of a deposition process, or comprised in the resulting deposited material on a substrate. For example, as discussed above, for a silicon germanium deposition process, the precoat layer (or the reactants to form the precoat layer) may comprise silicon and/or germanium, or compounds comprising one or both (for a silicon germanium precoat layer, the germanium concentration may be between 5% and 90% by weight germanium). As another example, for a deposition process to deposit a silicon phosphorus layer on a substrate, the precoat layer (or the reactants to form the precoat layer) may comprise silicon and/or phosphorus, or compounds comprising one or both. In various embodiments, a precoat layer (or the reactants to form the precoat layer) may comprise boron, phosphorus, arsenic, and/or the like, and/or compounds comprising any of the foregoing, depending on the deposition process following the precoat.

The precoating (i.e., the compounds used to form the precoat layer) may be applied to the reaction chamber in any suitable manner. For example, the precoating may be applied to the reaction chamber in a similar manner to the precursors discussed herein to form a silicon germanium film (or in a different manner). The compounds in the precoating may be one or more of the compounds comprised in the first silicon precursor, the second silicon precursor, and/or the germanium precursor, as discussed herein. The precoating may be applied to the reaction chamber for deposition on surfaces therein (including on any surfaces of components within the reaction chamber) in any suitable manner, including spraying, brushing, ALD, CVD, or the like. Based on the desired thickness of the precoating layer, conditions during the precoat deposition (e.g., temperature, pressure, etc.) may be varied to achieve faster or slower deposition of the precoat layer. For example, an environment within the reaction chamber may comprise an elevated temperature and/or pressure during precoat deposition to achieve faster deposition and/or a thicker precoat layer. As another example, an environment within the reaction chamber may comprise a relatively lower temperature and/or pressure during precoat deposition to achieve slower deposition and/or a thinner precoat layer. In various embodiments, the temperature during precoating deposition may be between a range of 400° C. to 1250° C. The pressuring during precoating deposition may be between a range of 2 Torr to 760 Torr. The flow rate of a precursor for precoat deposition (e.g., a silicon and/or germanium precursor) may comprise 5 sccm to 5000 sccm, again depending on the desired thickness of the precoat. The substrate may be heated after the precoating is applied thereto to form the precoat layer. The precoat layer may comprise any suitable thickness, such as between 20 Angstroms and 30 micrometers, between 20 Angstroms and 20 micrometers, between 1000 and 3000 Angstroms, or about 1000 Angstroms, or about 3000 Angstroms (the term “about” in this context means plus or minus ten percent of the subject value). In various embodiments, the thickness of the precoat may be less than, equal to, or greater than the desired thickness of the layer to be deposited on a substrate. The thickness of the precoat layer may depend on the desired effect of the precoat layer on the deposition of the film on a substrate (e.g., the desired effect on a silicon germanium layer deposited on a substrate, as discussed herein).

The precoat layer may improve the consistency or uniformity of the film thickness and/or germanium composition of the silicon germanium layer disposed on, and across, the substrate, including proximate the substrates edge(s) (e.g., as close as 1.2 millimeters (mm) or 1.0 mm, or even closer, from a substrate edge). Without being bound by theory, application of a precoat to surfaces within a reaction chamber may adjust the emissivity of such surfaces. Thus, the emissivity of surfaces surrounding the susceptor and/or substrate being processed within a reaction chamber may be adjusted by applying a precoat layer. Accordingly, the thermal radiation emission (e.g., infrared radiation) from the surfaces surrounding the substrate (e.g., on the susceptor, thermocouple ring, or the like) may be adjusted by precoat application. This change in the emissivity of surfaces surrounding the substrate being processed may change the temperature around different portions of the substrate, thus changing the deposition occurring at such portions of the substrate. For example, if the deposition of a film on a substrate is greater than desired in a certain substrate portion, a precoat may be applied to the surfaces of the reaction chamber to decrease the emissivity of surfaces proximate to such a substrate portion (or to all surfaces), thus lowering the temperature proximate to such substrate portion during processing. The decreased temperature (from decreased emitted thermal radiation) may slow deposition on that substrate portion relative to reaction chamber surfaces without a precoat layer. Likewise, to increase deposition on a certain substrate portion, a precoat may be applied to surfaces of the reaction chamber proximate to such substrate portion (or all surfaces) to increase the emissivity of those surfaces. Thus, the increased thermal radiation will increase the temperature proximate the substrate portion, increasing film deposition thereon during processing. Accordingly, the ability to add a precoat allows the adjustment of reaction conditions (e.g., temperature) at specific portions within a reaction chamber. Additionally, the amount of emissivity change of a surface can be adjusted to a desired level by the amount of precoat applied to the surface (e.g., by adjusting the thickness of the precoat layer, the precoat compositional makeup, and/or the concentration of one or more materials therein), or by using precoatings comprising different materials or compounds.

The precoat layer may further affect processing conditions because mass transfer between the precoat layer and the precursor flow and film deposition may occur. Therefore, to add more of one substance in a deposition process, a precoat may be applied to the reaction chamber comprising such substance. In various embodiments, as discussed above, a precoat may comprise one or more compounds or substances comprised in at least one of the reactants of a deposition process, or comprised in the resulting deposited material on a substrate, because then mass transfer from the precoat will not add unwanted compounds or contaminants into the deposited film or processing environment.

By utilizing a precoat layer, as discussed herein, the benefits of increased film uniformity (thickness and/or concentration) across a substrate may be achieved without need to change the compounds (e.g., precursors), temperature, pressure, flow rate, or other aspects of a process or recipe used to form a silicon germanium layer (or other film) on a substrate. That is, rather than adjusting the recipe for depositing a desired film on a substrate (i.e., the main deposition process) to change the deposition thereof (to increase uniformity), the precoat may be applied to the reaction chamber separately from the main deposition process, leaving the main deposition process unchanged. Therefore, better film/layer uniformity across a substrate may be achieved without having to adjust pre-established deposition processes or recipes.

These benefits of increased film uniformity, especially at the substrate edges, provide great value, for example, within the semiconductor industry. As electronic devices get smaller and smaller, die yield of the film deposited on a substrate has become more important. Relative uniformity of the deposited film is desired or required to produce sufficiently effective dies. Therefore, achieving greater uniformity of the film deposited on the substrate (e.g., the silicon germanium layer) allows greater die yield from the edges of the substrate film.

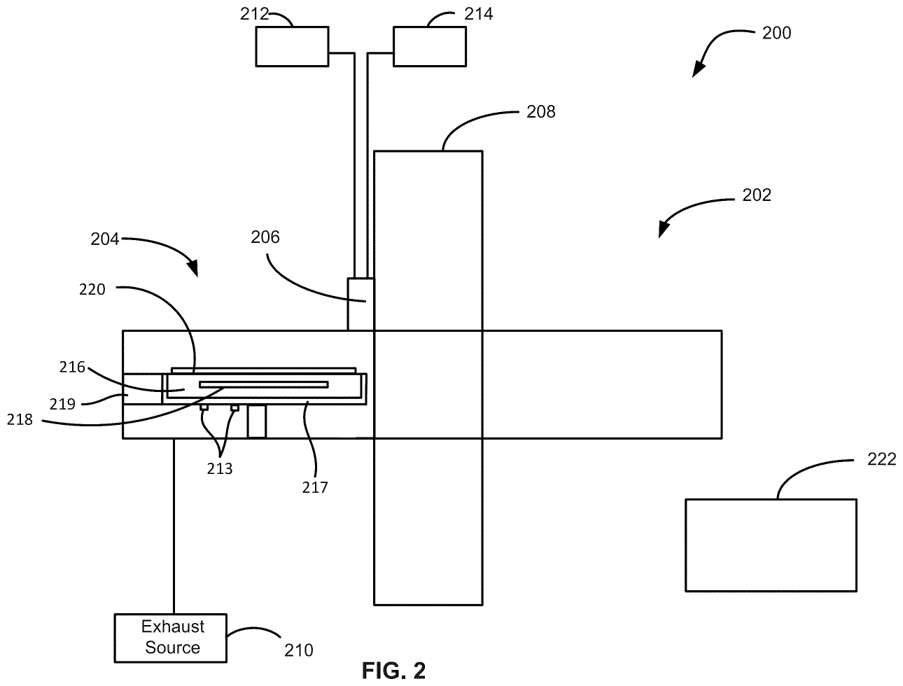

FIG. 2 illustrates an exemplary reactor system 200. Reactor system 200 can be used for a variety of applications, such as, for example, chemical vapor deposition (CVD) and the like. Although exemplary embodiments are described below in connection with epitaxial reactor systems, embodiments and the disclosure are not so limited, unless stated otherwise.

In the illustrated example, reactor system 200 includes an optional substrate handling system 202, a reaction chamber 204, a gas injection system 206, and optionally a wall 208 disposed between reaction chamber 204 and substrate handling system 202. System 200 can also include a first gas source 212, a second gas source 214, an exhaust source 210, a susceptor or substrate support 216, a thermocouple ring 217, and/or a getter plate 219. Although illustrated with two gas sources 212, 214, reactor system 200 can include any suitable number of gas sources. Further, reactor system 200 can include any suitable number of reaction chambers 204, which can each be coupled to a gas injection system 206. In the case in which reactor system 200 includes multiple reaction chambers, each gas injection system can be coupled to the same gas sources 212, 214 or to different gas sources.

Gas sources 212, 214 can include, for example, various combinations of one or more precursors, one or more dopant sources, one or more etchants, and mixtures of gases, including mixtures of one or more precursors, dopant sources, and/or etchants with one or more carrier gases.

By way of examples, first gas source 212 can include a first silicon precursor. In some cases, first gas source 212 can include a dopant and/or a carrier gas. Second gas source 214 can include the second silicon precursor or a mixture of the second silicon precursor and the germanium precursor. The first and second silicon precursors and the germanium precursor can be as described above.

Exemplary dopant sources include gases that include one or more of As, P, C, Ge, and B. By way of examples, the dopant source can include germane, diborane, phosphine, arsine, or phosphorus trichloride. The reactor systems and methods described herein may be particularly useful in forming p-type doped films, such as p-type doped films comprising silicon, silicon germanium, or the like.

Carrier gases can be or include one or more inert gases and/or hydrogen. Exemplary carrier gases include one or more gases selected from the group consisting of hydrogen, nitrogen, argon, helium, or the like.

Reactor system 200 can include any suitable number of reaction chambers 204 and substrate handling systems 202. Reaction chamber 204 of reactor system 200 can be or include, for example, a cross flow, cold wall epitaxial reaction chamber.

Susceptor 216 may comprise a substrate support surface upon which the substrate 220 rests for deposition processing. The substrate support surface may comprise a surface area that is equal to or larger than the size (or surface area) of the substrate. In embodiments in which the substrate support surface is larger than the substrate 220, a rim of susceptor 216 may protrude outside the surface area occupied by substrate 220 when substrate 220 is disposed on susceptor 216 (as shown in FIG. 2). Susceptor or substrate support 216 can include one or more heaters 218 to heat a substrate 220—e.g., to a temperature of about 500 to about 600, about 600 to about 700, or about 700 to about 800 degrees Celsius or other temperatures noted herein. Susceptor or substrate support 216 can also be configured to rotate during processing. In accordance with examples of the disclosure, susceptor or substrate support 216 rotates at a speed of about 90 to about 60, about 60 to about 30, about 30 to about 15, or about 15 to about 5 rotations per minute.

Thermocouple ring 217 may comprise an opening or cavity in which susceptor 216 may be disposed. Thermocouple ring 217 may surround susceptor 216, such that the thermocouple ring 217 and/or its opening or cavity is concentric with susceptor 216. In embodiments in which susceptor 216 is configured to rotate during processing, thermocouple ring 217 may remain static. Thermocouple ring 217 comprise one or more thermocouples 213 coupled thereto and/or disposed therein. Thermocouples may be disposed on or within thermocouple ring 217 in any suitable position. Thermocouple ring 217 may be configured to be heated or cooled (e.g., by thermocouples 213) to provide temperature control of susceptor 216 and/or substrate 220 to achieve desired thermal reaction conditions during deposition processing.

Getter plate 219 may attract unused reactants during processing, thus lowering deposition on other surfaces within reaction chamber 204. Getter plate may also play a role in temperature modulation within reaction chamber 204 during processing.

During operation of reactor system 200, substrates 220, such as semiconductor wafers, are transferred from, e.g., substrate handling system 202, to reaction chamber 204. Once substrate(s) 220 are transferred to reaction chamber 204, one or more gases from first and second gas sources 212, 214, such as precursors, dopants, carrier gases, etchants, and/or purge gases, are introduced into reaction chamber 204 via gas injection system 206. As set forth in more detail below, gas injection system 206 can be used to meter and control gas flow of one or more gases from first gas source 212 and second gas source 214 during substrate processing and to provide desired flows of such gas(es) to multiple sites or channels within reaction chamber 204.

System 200 can also include a controller 222. Controller 222 can be configured to control gas flow of a first silicon precursor, a second silicon precursor, and a germanium precursor (e.g., from one or more of first gas source 212 and second gas source 214) into at least one of the one or more reaction chambers 204 to form a layer comprising silicon germanium overlying a surface of a substrate using a deposition process (e.g., method 100, described above). As noted below, controller 222 can also be used to control a flow of one or more gasses into one or more channels of a gas injection system.

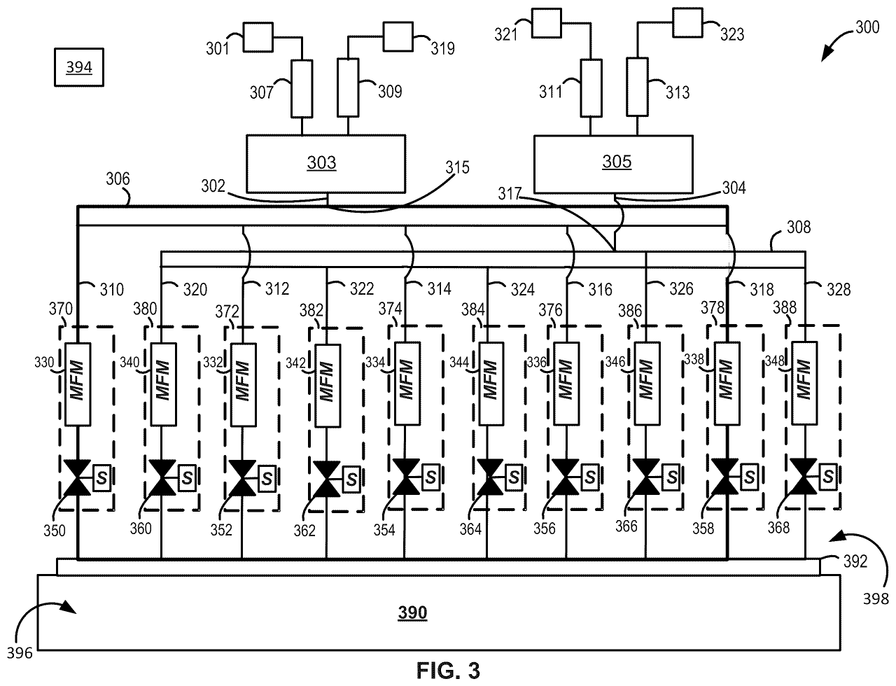

FIG. 3 schematically illustrates a gas injection system 300, suitable for use as gas injection system 206, in accordance with exemplary embodiments of the disclosure. Gas injection system 300 includes a first gas supply line 302 coupled to a first gas source 303, which can be the same or similar to gas source 212, and a second gas supply line 304 coupled to a second gas source 305, which can be the same or similar to gas source 214. When referring to gas lines and fluid components of gas injection system 300, the term coupled refers to fluidly coupled, and, unless stated otherwise, the lines or components need not be directly fluidly coupled, but rather gas injection system 300 can include other intervening elements, such as connectors, valves, meters, or the like.

Gas injection system 300 includes a first gas manifold 306 coupled to first gas supply line 302 via a first gas inlet 315 and a second gas manifold 308 coupled to second gas supply line 304 via a second gas inlet 317. First gas manifold 306 includes a plurality of first gas outlets 310-318. Similarly, second gas manifold 308 includes a plurality of second gas outlets 320-328. First gas manifold 306 and second gas manifold 308 are configured to receive gas from one or more gas lines (e.g., first and second gas lines 302, 304) and distribute the gas into one or more channels, which are respectively defined, in part, by first gas outlets 310-318 and second gas outlets 320-328. In the illustrated example, each of the first and second gas streams from first gas source 303 and second gas source 305 is divided into five gas channels. Although illustrated with five of each of first gas outlets 310-318 and second gas outlets 320-328, gas injection systems in accordance with this disclosure can include any suitable number of first, second, and/or other gas outlets, corresponding to a number of channels for the respective gases. For example, exemplary systems can include, for example, about 1-10 channels or include 5, 6, 7, 9, or more channels for each gas. As illustrated, first gas manifold 306 and/or second gas manifold 308 can include a loop configuration to facilitate even flow distribution through the gas channels. Additionally or alternatively, first gas manifold 306 and/or second gas manifold 308 can have a relatively large diameter relative to gas lines 302, 304—e.g., the diameter of first gas manifold 306 and/or second gas manifold 308 can be greater than 2, 3, 4, or 5 times larger than the diameter of line 302 and/or line 304. In the illustrated examples, first gas channels and second gas channels are alternatingly adjacent each other. However, this need not be the case.

As noted above, first gas source 303 and/or second gas source 305 can be a mixture of two or more gases. In such cases, one or more gases, which may, in turn, include a mixture of gases—or not, can be supplied from other sources (e.g., sources 301, 319, 321, 323), to first gas source 303 and/or second gas source 305 via flow controllers 307-313. When the source gases upstream of flow controllers 307-313 are not mixtures of gases, flow controllers 307-309 can suitably be mass flow controllers. One or more of flow controllers 307-313 can control a flow rate of a carrier gas to first gas source 303 and/or second gas source 305.

Gas injection system 300 additionally includes a plurality of flow sensors 330-348 coupled to first and second gas outlets 310-328. In the illustrated example, each first and second gas outlets 310-328 is coupled to a single flow sensor 330-348. However, in some cases, it may be desirable to have some gas outlets that are not coupled to a flow sensor and/or to have some gas outlets that are coupled to more than one flow sensor.

Flow sensors 330-348 can be used to monitor flow rates of gas mixtures and to provide real-time and/or historical flow rate information to a user for each channel—e.g., using a graphical user interface. Additionally or alternatively, flow sensors 330-348 can be coupled to a controller (e.g., controller 394, which can be the same or different from controller 222) and to gas valves 350-368 to provide controlled flow ratio of the gases through gas valves 350-368. By placing at least one flow sensor 330-348 in each gas channel, the flow ratio (e.g., relative flow rate) of gas through each channel can be measured and controlled, regardless of the gas composition. Exemplary flow sensors 330-348 can be or include various flow sensors, e.g., thermal mass flow sensors, pressure drop based flow sensors, or the like.

Gas valves 350-368 can include any suitable device to meter flow of a gas. In accordance with various embodiments of the disclosure, gas valves 350-368 each comprise proportional valves, such as solenoid valves, pneumatic valves, or piezoelectric valves. A valve with a relatively high (e.g., 0.021-0.14) flow coefficient (Cv) may be selected to reduce chocking downstream. Gas valves 350-368 may desirably operate under closed-loop control, but may also be capable (e.g., additionally) of operating under open-loop control.

Flow sensors 330-348 and gas valves 350-368 can initially form part of, for example, a mass flow controller (e.g., an off-the-shelf mass flow controller), wherein the control function of the valve is replaced by controller 394. For example, flow meter 330 and gas valve 350 can form or be part of a mass flow controller 370 that is set to operate in open-loop mode and wherein controller 394 provides closed-loop control of valves 350-368. Flow sensors 332-348 and gas valves 352-368 can similarly form or be part of a mass flow controller 372-388. This configuration allows for implementation in standard reactor configurations and/or for use of readily-available mass flow controllers and flow sensors and valves.

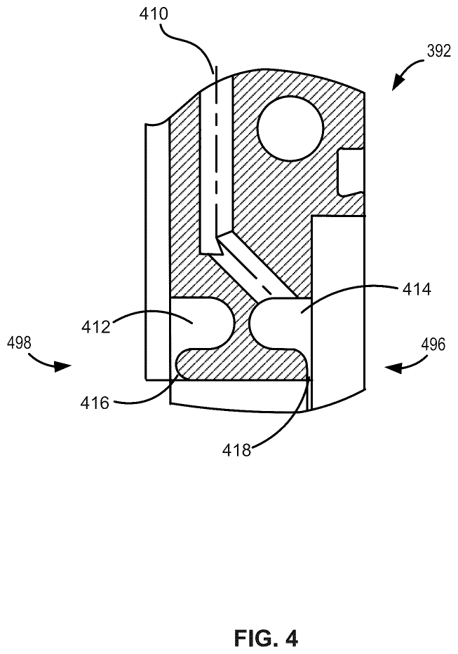

Gas valves 350-368 can be coupled to a reaction chamber 390 (which can be the same or similar to reaction chamber 204) via a flange 392. Additional line (e.g., tubing) and suitable connectors can be used to couple gas valves 350-368 to flange 392. Exemplary flange 392 includes flange gas channels to maintain the channels until the respective gases exit into reaction chamber 390; one exemplary flange gas channel 410 is illustrated in FIG. 4. Flange gas channels can include expansion areas 412, 414 and respective outlets 416, 418, which terminate at opposite sides of the flange and adjacent each other. For example, the first gas channels, corresponding to first gas streams, can terminate at a first side 496 of flange 392 and the second gas channels, corresponding to second gas streams, can terminate at a second side 498 of flange 392.

Systems and methods described herein improve the concentration profile components (e.g., silicon and germanium) within a film deposited using the systems and/or methods. In accordance with examples of the disclosure, a non-uniformity of a concentration of a component from center to edge (or a distance of about 1 mm from the edge) of the substrate (formed in a reaction chamber without a precoat layer disposed on the surfaces therein) varied less than 10%, less than 2%, and less than 1%—even with the relatively high concentrations of germanium.

As noted above, in accordance with at least one embodiment of the disclosure, first gas inlet 315 can receive a first gas comprising a first silicon precursor (e.g., halogenated silicon precursor) and optionally an additional dopant source, and second gas inlet 304 can receive a second gas comprising a second silicon precursor (e.g., nonhalogenated silicon precursor) and a germanium precursor.

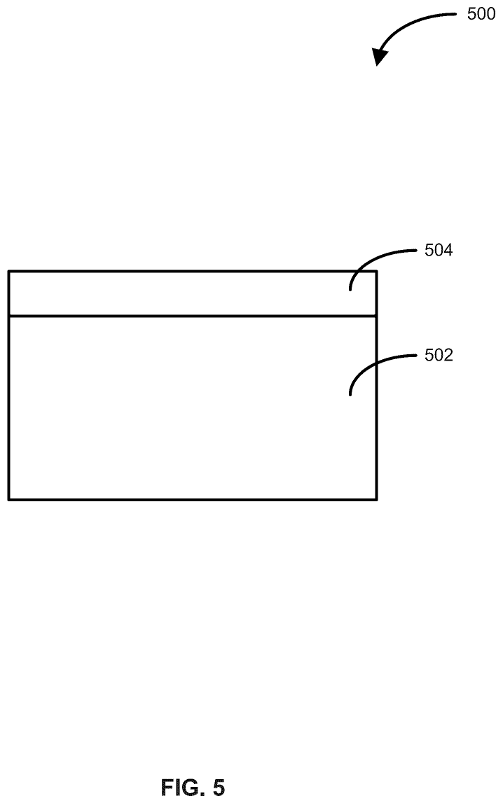

Turning now to FIG. 5, a structure 500 in accordance with examples of the disclosure is illustrated. Structure 500 includes a substrate 502 and a silicon germanium layer 504. Substrate 502 can be or include a substrate as described herein. Silicon germanium layer 504 can be formed using a method and/or system as described herein. Silicon germanium layer 504 may be used for a variety of applications, including, for example channel, source, and/or drain regions in a MOS or CMOS device, such as, for example, a PMOS device.

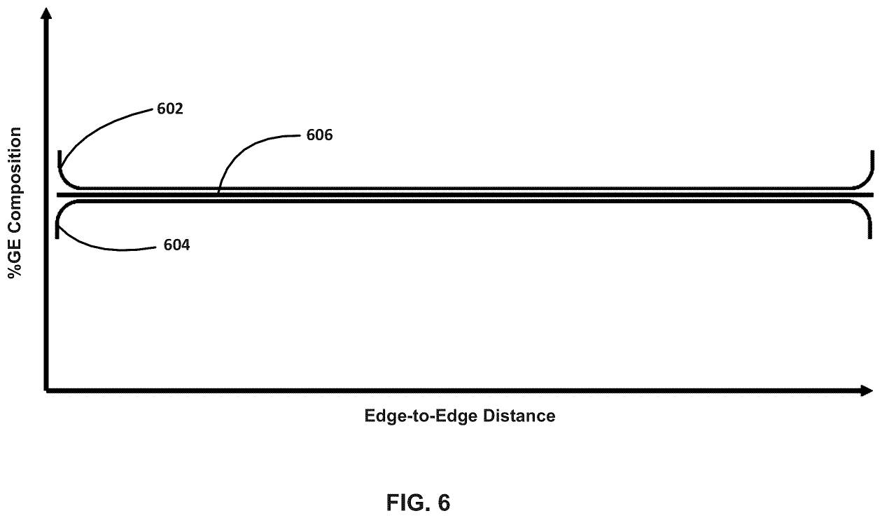

As noted above, methods and systems described herein can be used to form silicon germanium layers with improved composition and/or thickness uniformity (less variability). FIG. 6 illustrates data 602 corresponding to a silicon germanium layer formed on a substrate (in a reaction chamber without a precoat layer disposed on the surfaces therein) using a nonhalogenated silicon precursor and a germanium precursor; data 604 corresponding to a silicon germanium layer formed using a halogenated silicon precursor and a germanium precursor; and data 606 corresponding to a silicon germanium layer formed using a halogenated silicon precursor and a nonhalogenated silicon precursor and a germanium precursor (e.g., mixed with the nonhalogenated silicon precursor). As shown, using a plurality of silicon precursors significantly improves edge-to-edge composition uniformity of the silicon germanium layer.

In various embodiments, the presence of a precoat layer on the surfaces within a reaction chamber prior to disposing a silicon germanium layer on a substrate therein may further facilitate improved germanium composition and/or thickness uniformity (or less variability thereof) of a silicon germanium layer on and along a substrate (e.g., edge-to-edge thickness and/or composition uniformity). In various embodiments, such an improvement may be the result of the adjusted emissivities of surfaces within the reaction chamber resulting from such surfaces comprising a precoat layer, as discussed herein. Additionally, the precoat layer may be adjusted (e.g., the layer thickness, concentration of certain components, etc.) to further adjust the deposition results on a substrate.

In various embodiments, nonuniformities of a film disposed on a substrate may be most significant at the edge of the substrate. Therefore, because surfaces proximate the edge of the substrate (e.g., a rim of the susceptor extending past the area occupied by the substrate, the thermocouple ring surrounding the susceptor, and/or the like) comprise a precoat, such surfaces comprise adjusted emissivities, thus adjusting the thermal radiation in such areas, which, in turn, modifies the deposition processing result on the substrate edge (e.g., making the film more uniform in thickness and/or component composition at the substrate edge).

In various embodiments, the presence of a precoat layer on surfaces within a reaction chamber prior to disposing a silicon germanium layer on a substrate therein may result in the concentration of a component (e.g., weight percentage germanium) within the silicon germanium layer varying from center to edge of the substrate (or to a distance of about 1 mm from the edge) less than 1%, less than 0.5%, between 0.2% and 0.5%, or about 0.3%. That is, the presence of a precoat layer on surfaces within a reaction chamber prior to disposing a silicon germanium layer on a substrate therein during a deposition process may result in significantly improved edge-to-edge germanium composition uniformity of the silicon germanium layer.

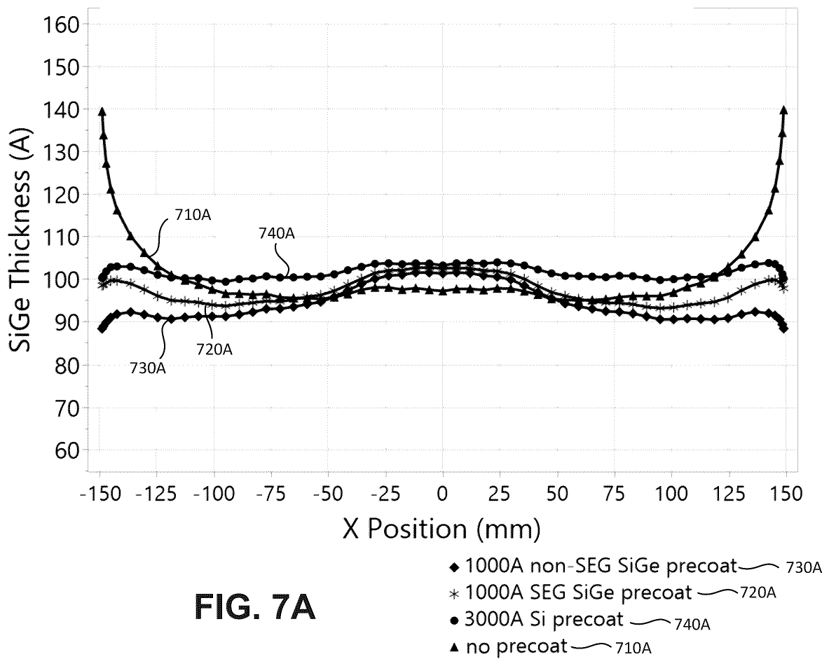

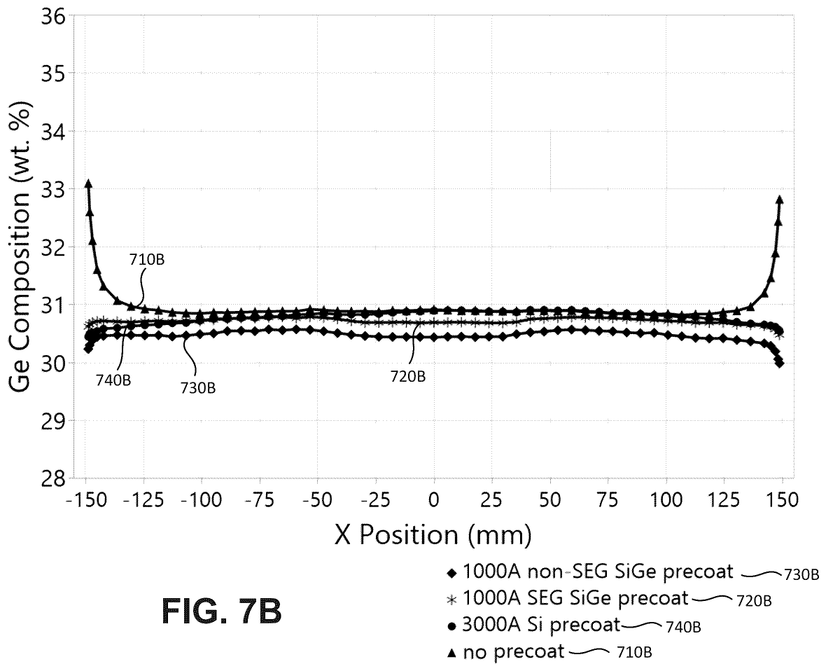

FIGS. 7A-9B illustrate germanium composition and thickness data for silicon germanium layers formed on a substrate in a reaction chamber having a precoat layer disposed on surfaces within the reaction chamber, in accordance with various embodiments.

FIG. 7A illustrates silicon germanium layer thicknesses (i.e., a thickness profile) across a substrate (e.g., a wafer) (i.e., FIG. 7A illustrates the effects of a precoat layer on a co-flow silicon germanium film thickness profile uniformity). In the thickness profiles described herein, the x-axis represents the position along the substrate, where the zero position is the center of the substrate, and extending in either direction along the x-axis indicates a position toward a respective edge of the substrate. Data sets 710A-740A represent silicon germanium layer thicknesses for silicon germanium layers prepared with a first silicon precursor comprising a halogenated silicon precursor (e.g., dichlorosilane) and a second silicon precursor comprising a nonhalogenated silicon precursor (e.g., silane) (the two silicon precursors being referred to as “co-flow” in FIGS. 7A and 7B), and a germanium precursor, in accordance with various embodiments. As shown by data set 710A (representing a co-flow silicon germanium process without a precoat), the represented silicon germanium layer on a substrate (formed in a reaction chamber without a precoat layer) has a significant increase in thickness toward the edges of the substrate. This creates undesirable variability of the silicon germanium layer along the substrate. Data sets 720A-740A however, indicate how including a precoat layer on the surfaces within a reaction chamber, in which a silicon germanium layer will be formed on a substrate, improves (i.e., decreases) the thickness variability of the silicon germanium layer on or across the substrate. Data set 720A represents a substrate having a silicon germanium layer deposited thereon (e.g., produced by a co-flow process) within a reaction chamber having a 1000-Angstrom selective epitaxial growth (SEG) precoat layer comprising silicon germanium disposed on surfaces therein (i.e., on the surfaces within the reaction chamber, including on surfaces of components within the reaction chamber such as a susceptor, thermocouple ring, getter plate, and/or the like). Data set 730A represents a substrate having a silicon germanium layer deposited thereon (e.g., produced by a co-flow process) within a reaction chamber having a 1000-Angstrom non-SEG precoat layer comprising silicon germanium disposed on surfaces therein. Data set 740A represents a substrate having a silicon germanium layer deposited thereon (e.g., produced by a co-flow process) within a reaction chamber having a 3000-Angstrom precoat layer comprising silicon (e.g., polycrystalline silicon) disposed on surfaces therein. As data sets 720A-740A indicate, the presence of a precoat layer (whether comprising silicon germanium or silicon) within the reaction chamber in which the silicon germanium layer is deposited greatly reduces the edge roll-up (i.e., the increase in thickness toward the substrate edges), and thus reduces the variability in the silicon germanium layer thickness across the substrate and increases the thickness uniformity, wherein the silicon germanium layer is formed with the two silicon precursors (halogenated and nonhalogenated) and the germanium precursor described above.

FIG. 7B illustrates the germanium composition percentage within silicon germanium layers across a substrate (i.e., FIG. 7B illustrates the effects of a precoat layer on a co-flow silicon germanium film germanium composition profile uniformity). In the germanium percentage profiles described herein, the x-axis represents the position along the substrate, where the zero position is the center of the substrate, and extending in either direction along the x-axis indicates a position toward a respective edge of the substrate. Data sets 710B-740B represent the percent (e.g., weight percent) of silicon germanium layers comprising germanium, wherein the silicon germanium layers are prepared with a first silicon precursor comprising a halogenated silicon precursor (e.g., dichlorosilane) and a second silicon precursor comprising a nonhalogenated silicon precursor (e.g., silane), and the germanium precursor, in accordance with various embodiments. As shown by data set 710B (representing a co-flow silicon germanium process without a precoat), the represented silicon germanium layer on a substrate formed in a reaction chamber without a precoat layer comprises a significant increase in germanium content toward the edges of the substrate. This creates undesirable variability of germanium content or composition within the silicon germanium layer along the substrate. In this case, a germanium composition percentage within the silicon germanium layer varies about 2.4% across the substrate. Data sets 720B-740B however, indicate how including a precoat layer on the surfaces within a reaction chamber, in which a silicon germanium layer will be formed on a substrate, improves (i.e., decreases) the germanium composition variability within or across the wafer. Data set 720B represents a substrate having a silicon germanium layer deposited thereon (e.g., produced by a co-flow process) within a reaction chamber having a 1000-Angstrom SEG precoat layer comprising silicon germanium disposed on surfaces therein. Data set 730B represents a substrate having a silicon germanium layer deposited thereon (e.g., produced by a co-flow process) within a reaction chamber having a 1000-Angstrom non-SEG precoat layer comprising silicon germanium disposed on surfaces therein. Data set 740B represents a substrate having a silicon germanium layer deposited thereon (e.g., produced by a co-flow process) within a reaction chamber having a 3000-Angstrom precoat layer comprising silicon (e.g., polycrystalline silicon) disposed on surfaces therein. As data sets 720B-740B indicate, the presence of a precoat layer (whether comprising silicon germanium or silicon) within the reaction chamber in which the silicon germanium layer is deposited greatly reduces the edge roll-up (i.e., the increase in germanium composition percentage of the silicon germanium layer toward the substrate edges), and thus reduces the variability in the silicon germanium layer composition across the substrate and increases composition uniformity. For example, the variability of the germanium percentage in the silicon germanium layer composition for data set 720B was about 0.3%, which is a significant improvement from the 2.4% variability without the precoat layer (shown in data set 710B).

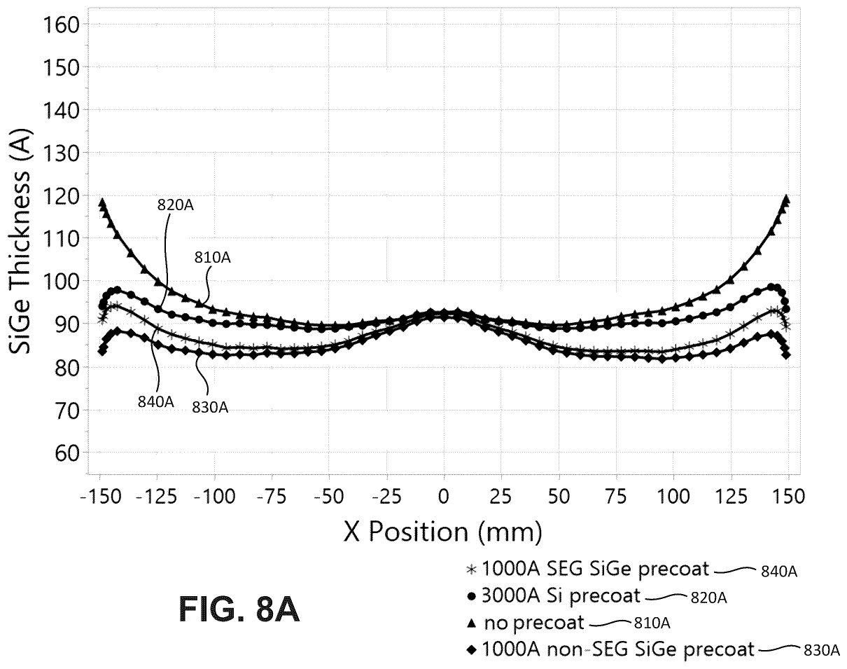

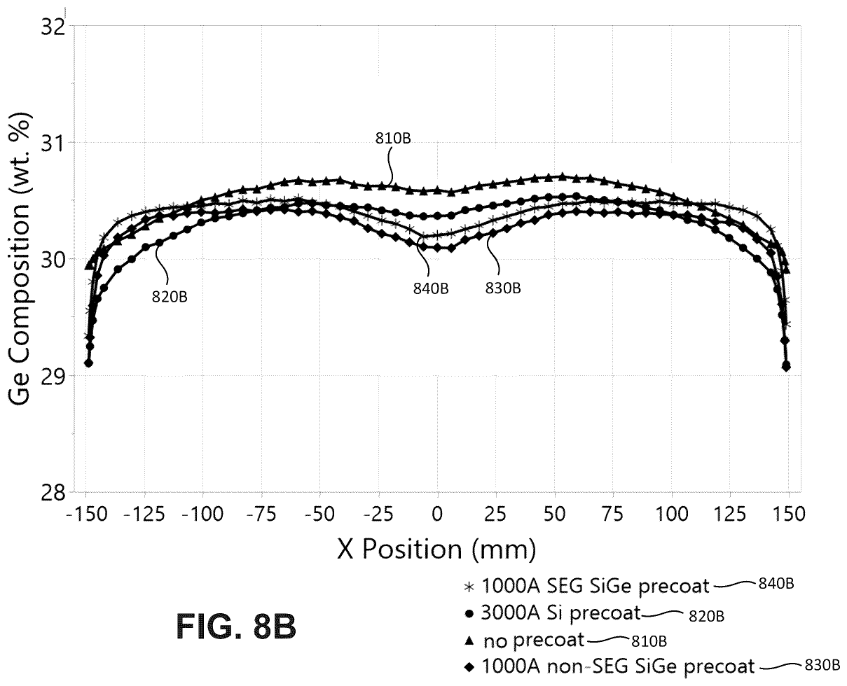

FIG. 8A illustrates the silicon germanium layer thicknesses (i.e., a thickness profile) across a substrate (e.g., a wafer) (i.e., FIG. 8A illustrates the effects of a precoat layer on a DCS-based silicon germanium film thickness profile uniformity). Data sets 810A-840A represent silicon germanium layer thicknesses for silicon germanium layers prepared with the silicon precursor comprising a halogenated silicon compound (e.g., dichlorosilane (DCS)) (no second silicon precursor) and a germanium precursor, in accordance with various embodiments. As shown by data set 810A (representing a DCS-based silicon germanium process without a precoat), the represented silicon germanium layer on a substrate formed in a reaction chamber without a precoat layer has a significant increase in thickness toward the edges of the substrate. This creates undesirable thickness variability of the silicon germanium layer along the substrate. Data sets 820A-840A however, indicate how including a precoat layer on the surfaces within a reaction chamber, in which a silicon germanium layer will be formed on a substrate, improves (i.e., decreases) the thickness variability within or across the wafer or substrate. Data set 820A represents a substrate having a silicon germanium layer deposited thereon (e.g., produced by a DCS-based process) within a reaction chamber having a 3000-Angstrom precoat layer comprising silicon (e.g., polycrystalline silicon) disposed on surfaces therein. Data set 830A represents a substrate having a silicon germanium layer deposited thereon (e.g., produced by a DCS-based process) within a reaction chamber having a 1000-Angstrom non-SEG precoat layer comprising silicon germanium disposed on surfaces therein. Data set 840A represents a substrate having a silicon germanium layer deposited thereon (e.g., produced by a DCS-based process) within a reaction chamber having a 1000-Angstrom SEG precoat layer comprising silicon germanium disposed on surfaces therein. As data sets 820A-840A indicate, the presence of a precoat layer (whether comprising silicon germanium or silicon) within the reaction chamber in which the silicon germanium layer is deposited greatly reduces the edge roll-up (i.e., increase in thickness toward the substrate edges), and thus reduces the variability in the silicon germanium layer thickness across the substrate and improves the thickness uniformity.

In various embodiments, the presence of a precoat layer within the reaction chamber may not significantly improve uniformity of the germanium composition percentage in the silicon germanium layer. FIG. 8B illustrates the effects of a precoat layer on a DCS-based silicon germanium film germanium composition profile uniformity. As shown in FIG. 8B, data sets 810B-840B represent the weight percent of silicon germanium layers comprising germanium, wherein the silicon germanium layers are prepared with the silicon precursor comprising a halogenated silicon compound (e.g., dichlorosilane) (no second silicon precursor) and the germanium precursor, in accordance with various embodiments. Data set 810B represents a silicon germanium layer on a substrate (e.g., produced by a DCS-based process) formed in a reaction chamber without a precoat layer. Data set 820B represents a silicon germanium layer on a substrate (e.g., produced by a DCS-based process) formed in a reaction chamber having a 3000-Angstrom precoat layer comprising silicon (e.g., polycrystalline silicon) disposed on the surfaces therein. Data set 830B represents a silicon germanium layer on a substrate (e.g., produced by a DCS-based process) formed in a reaction chamber having a 1000-Angstrom non-SEG precoat layer comprising silicon germanium disposed on the surfaces therein. Data set 840B represents a silicon germanium layer on a substrate (e.g., produced by a DCS-based process) formed in a reaction chamber having a 1000-Angstrom SEG precoat layer comprising silicon germanium disposed on the surfaces therein. As shown by data sets 810B-840B, the presence of a precoat layer on surfaces within the reaction chamber in which the silicon germanium layer is deposited does not significantly affect or improve the roll-down (i.e., the decrease in germanium percentage within the silicon germanium layer) near the substrate edges.

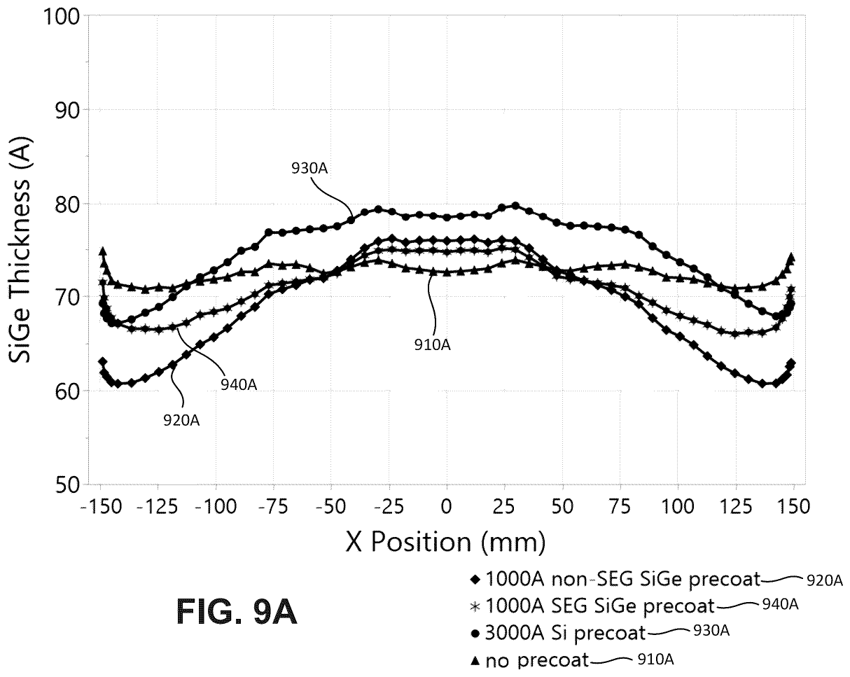

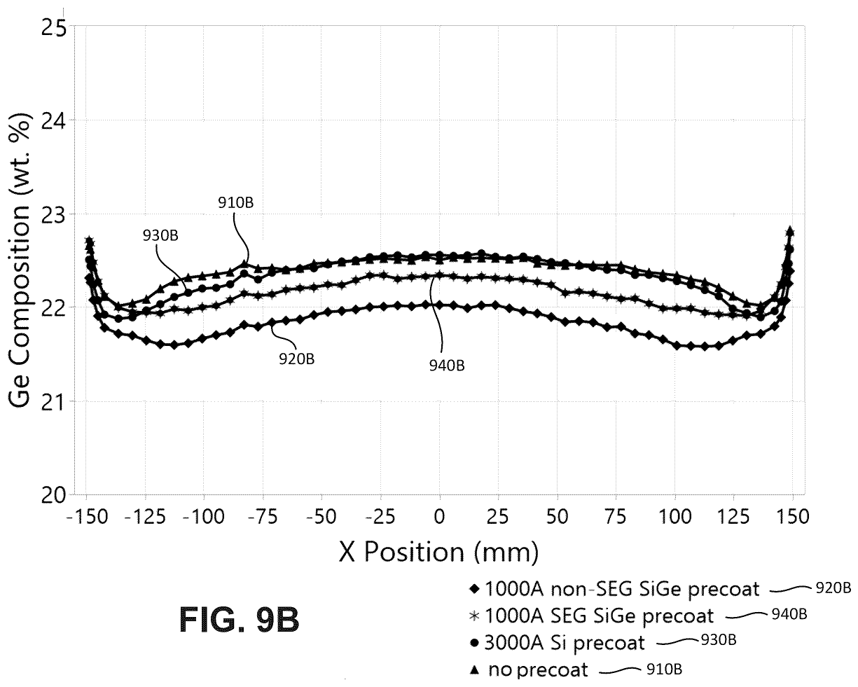

FIG. 9A illustrates the silicon germanium layer thicknesses (i.e., a thickness profile) across a substrate (e.g., a wafer) (i.e., FIG. 9A illustrates the effects of a precoat layer on a silane-based silicon germanium film thickness profile uniformity). Data sets 910A-940A represent silicon germanium layer thicknesses for silicon germanium layers prepared with the silicon precursor comprising a nonhalogenated silicon compound (e.g., silane) (no second silicon precursor), and the germanium precursor, in accordance with various embodiments. Data set 910A represents a silicon germanium layer on a substrate (e.g., produced by a silane-based process) formed in a reaction chamber without a precoat layer. Data set 920A represents a silicon germanium layer on a substrate (e.g., produced by a silane-based process) formed in a reaction chamber having a 1000-Angstrom non-SEG precoat layer comprising silicon germanium disposed on the surfaces therein. Data set 930A represents a silicon germanium layer on a substrate (e.g., produced by a silane-based process) formed in a reaction chamber having a 3000-Angstrom precoat layer comprising silicon (e.g., polycrystalline silicon) disposed on the surfaces therein. Data set 940A represents a silicon germanium layer on a substrate (e.g., produced by a silane-based process) formed in a reaction chamber having a 1000-Angstrom SEG precoat layer comprising silicon germanium disposed on the surfaces therein. As shown by data set 910A-940A, the presence of a precoat layer on surfaces within the reaction chamber in which the silicon germanium layer is deposited may not significantly improve the thickness uniformity of the represented silicon germanium layer along the substrate.

FIG. 9B illustrates the germanium composition percentage of silicon germanium layers across a substrate (i.e., FIG. 9B illustrates the effects of a precoat layer on a silane-based silicon germanium film germanium composition profile uniformity). Data sets 910B-940B represent the weight percent of the respective silicon germanium layers comprising germanium, wherein the silicon germanium layer is prepared with the silicon precursor comprising a nonhalogenated silicon compound (e.g., silane) (no second silicon precursor), and a germanium precursor, in accordance with various embodiments. Data set 910B represents a silicon germanium layer on a substrate (e.g., produced by a silane-based process) formed in a reaction chamber without a precoat layer. Data set 920B represents a silicon germanium layer on a substrate (e.g., produced by a silane-based process) formed in a reaction chamber having a 1000-Angstrom non-SEG precoat layer comprising silicon germanium disposed on the surfaces therein. Data set 930B represents a silicon germanium layer on a substrate (e.g., produced by a silane-based process) formed in a reaction chamber having a 3000-Angstrom precoat layer comprising silicon (e.g., polycrystalline silicon) disposed on the surfaces therein. Data set 940B represents a silicon germanium layer on a substrate (e.g., produced by a silane-based process) formed in a reaction chamber having a 1000-Angstrom SEG precoat layer comprising silicon germanium disposed on the surfaces therein. As shown by data sets 910B-940B, the presence of a precoat layer on surfaces within the reaction chamber in which the silicon germanium layer is deposited may not significantly affect or improve the germanium composition percentage uniformity of the silicon germanium layer along the substrate.

In light the results shown in FIGS. 7A-7B versus those shown in FIGS. 8A-8B and 9A-9B, the presence of a precoat layer on surfaces within the reaction chamber may further improve the thickness and germanium content uniformity of a silicon germanium layer across a substrate in embodiments involving both a halogenated silicon precursor (e.g., dichlorosilane) and a nonhalogenated precursor (e.g., silane), along with the germanium precursor (indicated in FIGS. 7A-7B). However, a silicon germanium layer formed through a process comprising a single silicon precursor may not receive significant benefits from the inclusion of a precoat layer (indicated in FIGS. 8A-8B and 9A-9B).

Although exemplary embodiments of the present disclosure are set forth herein, it should be appreciated that the disclosure is not so limited. For example, although systems are described in connection with various specific configurations, the disclosure is not necessarily limited to these examples. Various modifications, variations, and enhancements of the systems and methods set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

1. A structure comprising a silicon germanium layer formed according to a method of forming the silicon germanium layer on a surface of a substrate, the method comprising the steps of:
providing the substrate within a reaction chamber;
providing a first silicon precursor to the reaction chamber;
providing a second silicon precursor to the reaction chamber; and
providing a germanium precursor to the reaction chamber,
wherein the steps of providing the first silicon precursor to the reaction chamber, providing the second silicon precursor to the reaction chamber, and providing the germanium precursor to the reaction chamber overlap.

2. The structure of claim 1, wherein the first silicon precursor consists of a halogenated silicon precursor.

3. The structure of claim 2, wherein the halogenated silicon precursor comprises a compound represented by a formula SiₓW_{y}H_{z}, wherein W is a halide selected from the group consisting of fluorine, chlorine, bromine, and iodine, x and y are integers greater than zero, and z is an integer greater than or equal to zero.

4. The structure of claim 2, wherein the halogenated silicon precursor comprises a compound selected from the group consisting of trichlorosilane, dichlorosilane, silicon tetrachloride, a silicon bromide, and a silicon iodide.

5. The structure of claim 1, wherein the second silicon precursor consists of a nonhalogenated silicon precursor.

6. A device comprising a silicon germanium layer formed according to a method of forming the silicon germanium layer on a surface of a substrate, the method comprising the steps of:
providing the substrate within a reaction chamber;
providing a first silicon precursor to the reaction chamber;
providing a second silicon precursor to the reaction chamber; and
providing a germanium precursor to the reaction chamber,
wherein the steps of providing the first silicon precursor to the reaction chamber, providing the second silicon precursor to the reaction chamber, and providing the germanium precursor to the reaction chamber overlap.

7. The device of claim 6, wherein the first silicon precursor consists of a halogenated silicon precursor.

8. The device of claim 7, wherein the halogenated silicon precursor comprises a compound represented by a formula SiₓW_{y}H_{z}, wherein W is a halide selected from the group consisting of fluorine, chlorine, bromine, and iodine, x and y are integers greater than zero, and z is an integer greater than or equal to zero.

9. The device of claim 7, wherein the halogenated silicon precursor comprises a compound selected from the group consisting of trichlorosilane, dichlorosilane, silicon tetrachloride, a silicon bromide, and a silicon iodide.

10. The device of claim 6, wherein the second silicon precursor consists of a nonhalogenated silicon precursor.

11. A method of forming a deposition layer on a substrate, comprising:
applying a precoating layer to a surface within a reaction chamber;
providing the substrate within the reaction chamber having the precoating layer;
providing a first reactant to the reaction chamber;
providing a second reactant to the reaction chamber; and
forming the deposition layer on the substrate, wherein the deposition layer comprises a product of the first reactant and the second reactant, and
wherein the precoating layer comprises a substance comprised in at least one of the first reactant, the second reactant, or the deposition layer.

12. The method of claim 11, wherein a germanium concentration of the precoating layer during the step of applying the precoating layer is chosen to reduce nonuniformity of the deposition layer at an edge of the deposition layer.

13. The method of claim 11, wherein the precoating layer is applied to a thickness between about 1000 Angstroms and about 3000 Angstroms.

14. The method of claim 11, wherein the step of providing the substrate within the reaction chamber comprises heating the substrate to a temperature of less than 600° C.

15. The method of claim 12, wherein the edge of the deposition layer is an area of the deposition layer about 1.2 millimeters from a substrate edge

16. The method of claim 12, wherein the first reactant comprises a silicon precursor and the second reactant comprises a germanium precursor.

17. The method of claim 16, wherein the germanium precursor comprises one or more of germanium tetrachloride, germanium chlorohydride, germanium chlorobromide.

18. The method of claim 16, wherein the silicon precursor comprises a compound selected from the group consisting of trichlorosilane, dichlorosilane, silicon tetrachloride, a silicon bromide, and a silicon iodide.

19. A system comprising:
one or more reaction chambers;
a first silicon precursor source;
a second silicon precursor source;
a germanium precursor source;
an exhaust source; and
a controller,
wherein the controller is configured to control gas flow of a first silicon precursor, a second silicon precursor, and a germanium precursor into at least one of the one or more reaction chambers to form a layer comprising silicon germanium overlying a surface of a substrate using a deposition process.

20. The system of claim 19, wherein the controller is configured to control the system by:
providing a first silicon precursor to the one or more reaction chambers from the first silicon precursor source;
providing a second silicon precursor to the one or more reaction chambers from the second silicon precursor source; and
providing a germanium precursor to the one or more reaction chambers from the germanium precursor source.
